(19) United States
(12) Patent Application Publication
(10) Pub. No.: US 2026/0068547 A1
(43) Pub. Date: Mar. 5, 2026

(54) MEMRISTIVE COMPUTING SCHEMES IN THE BACK-END-OF-THE-LINE

(71) Applicants: Applied Materials, Inc., Santa Clara, CA (US); National University of Singapore, Singapore (SG)

(72) Inventors: Hippolyte P.A.G. Astier, Singapore (SG); Muhammed Juvaid Mangattuchali, Singapore (SG); Chandan Das, Singapore (SG); John Sudijono, Singapore (SG); Silvija Gradecak-Garaj, Singapore (SG)

(73) Assignees: Applied Materials, Inc., Santa Clara, CA (US); National University of Singapore, Singapore (SG)

(21) Appl. No.: 18/816,431

(22) Filed: Aug. 27, 2024

(51) Int. Cl. H10N 70/00; H10B 63/00; H10N 70/20

(52) U.S. Cl. CPC H10N 70/8833; H10B 63/30; H10N 70/023; H10N 70/253; H10N 70/8822; H10N 70/8825; H10N 70/8828

(57) ABSTRACT

Provided are ultrathin films for use as modulable-resistance channels (memristors, resistive switches, synaptic nodes/synaptic emulators, hysteretic resistors, ReRAM or RRAM, transistors, memtransistors) in the back-end-of-line (BEOL) applications, thus, combining two logic nodes in the BEOL and the front-end-of-line (FEOL). Transition metal dichalcogenides (TMDC) films, other 2D material films, metal oxide films, metal carboxide films, metal nitride oxide films, and a nitride films are provided for modulable-resistance channel (memristors, resistive switches, synaptic nodes/synaptic emulators, hysteretic resistors, ReRAM or RRAM, transistors, memtransistors) material applications in BEOL processes. Also provided are computing schemes making use of the modulable-resistance components.

### TECHNICAL FIELD

Embodiments of the disclosure generally relate to the formation of ultrathin films for use as modulable-resistance channel (memristors, resistive switches, synaptic nodes/synaptic emulators, hysteretic resistors, ReRAM or RRAM, transistors, memtransistors) in the back-end-of-line (BEOL) applications, thus, enabling the combination of logic and/or memory nodes in both the BEOL and the front-end-of-line (FEOL). More specifically, methods of forming transition metal dichalcogenides (TMDC) films, metal oxide films, nitride films, and other 2D material films are provided for modulable-resistance channel (memristors, resistive switches, synaptic nodes/synaptic emulators, hysteretic resistors, ReRAM or RRAM, transistors, memtransistors) material applications in back-end-of-line (BEOL) processes. Embodiments also relate to computing schemes making use of the modulable-resistance components.

### BACKGROUND

Memristors are a class of electronic components whose conductance is modulated by their operation history. These can produce multi-state or even analogue systems modulated by the history of the current across it. Several classes of materials can produce this behavior, such as oxides and 2D materials.

The combined logic and memory functions can be used to replicate deep-learning networks with memristors emulating weight nodes. Neuromorphic computing benefits from memory plasticity, i.e., the dependence of the node's training or programming on the parameters of the signal it receives, such as its amplitude, duration, rate, or delay.

Several computing schemes can utilize hysteresis or memory properties in resistors. These include the use of conductance weighting nodes in an array, in which they can act as on-off, multistate, or analogue switches. These switches can be trained by the operation history, such that a hardware training scheme can determine the weights of the nodes before operation. Alternatively, they can be trained dynamically by the operation to adapt to it.

Some computing schemes make use of plasticity, to integrate schemes in which nodes are trained dynamically by voltage or current signals in which the resulting training (determining the conductance of weighting nodes) depends on various properties of the voltage/current signal: signal shape, amplitude, duration, and rate. Typical examples of such schemes utilize voltage pulses (square or other) with controlled amplitude, duration, and rate.

In addition to modulable resistors, some three-terminal components can be made to integrate memory properties. These include memtransistors, whereby a gate can electrostatically modulate the conductance of a memristor. They may also include a transistor whose electrostatic gate is modulated by a memory resistor.

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

The advancing complexity of advanced microelectronic devices is placing stringent demands on currently used materials and deposition techniques. Accordingly, there is an ongoing need in the art for methods of producing high quality films for use in integrated circuit structures.

### SUMMARY

One or more embodiments of the disclosure are directed to interconnect devices. In one or more embodiments, an interconnect device comprises: a substrate; and a modulable-resistance channel formed therein.

Other embodiments of the disclosure are directed to memory dependent computation schemes. In one or more embodiments, a memory dependent computation scheme comprises a modulable-resistance channel as a conductance node.

Further embodiments of the disclosure are directed to non-von Neuman computing schemes comprising the memory dependent computation scheme of one or more embodiments.

Still further embodiments of the disclosure are directed to neuromorphic computing schemes comprising the memory dependent computation scheme of one or more embodiments.

Additional embodiments of the disclosure are directed to methods of forming a modulable-resistance channel on a substrate. In one or more embodiments, the method comprises: exposing a substrate to metal precursor, the substrate comprising an opening formed in a dielectric layer; and exposing the substrate to a second precursor to form the modulable-resistance channel in the opening.

Further embodiments of the disclosure are directed to methods of forming a memristor on a semiconductor substrate. In one or more embodiments, a method of forming a memristor on a semiconductor substrate comprises: forming a memristor in a process cycle comprising sequential exposure of a substrate to a metal precursor, a first purge gas, a chalcogen-containing precursor, and a second purge gas, the substrate comprising a dielectric layer having a via opening formed therein, the memristor formed in the via opening as an integrated circuit node.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method in accordance with one or more embodiments of the disclosure;

FIG. 2A illustrates a cross-section schematic of an integrated circuit in accordance with one or more embodiments of the disclosure;

FIG. 2B illustrates a cross-section schematic of an integrated circuit in accordance with one or more embodiments of the disclosure;

FIGS. 3A to 3C illustrate cross-section schematics of an integrated circuit in accordance with one or more embodiments of the disclosure;

FIGS. 4A to 4C illustrate cross-section schematics of an integrated circuit in accordance with one or more embodiments of the disclosure;

FIGS. 5A to 5C illustrate cross-section schematics of an integrated circuit in accordance with one or more embodiments of the disclosure;

FIGS. 6A to 6C illustrate cross-section schematics of an integrated circuit in accordance with one or more embodiments of the disclosure;

FIGS. 7A to 7C illustrate cross-section schematics of an integrated circuit in accordance with one or more embodiments of the disclosure;

FIGS. 8A to 8C illustrate cross-section schematics of an integrated circuit in accordance with one or more embodiments of the disclosure;

FIGS. 9A to 9C illustrate cross-section schematics of an integrated circuit in accordance with one or more embodiments of the disclosure;

FIGS. 10A to 10C illustrate cross-section schematics of an integrated circuit in accordance with one or more embodiments of the disclosure;

FIGS. 11A and 11B illustrate cross-section schematics of an integrated circuit in accordance with one or more embodiments of the disclosure; and

FIGS. 12A and 12B illustrate cross-section schematics of an integrated circuit in accordance with one or more embodiments of the disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

Atomic layer deposition (ALD) and chemical vapor deposition (CVD) are deposition processes employed for depositing layers on a substrate. ALD and CVD deposition techniques require precise control of the substrate temperature and the precursors introduced into the processing chamber in order to produce a desired layer of uniform thickness. These requirements become more critical as substrate size changes, creating a need for more complexity in chamber design and gas flow technique to maintain adequate uniformity. The deposition method may be a CVD process or an ALD process.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

In one or more embodiments, ultrathin materials can be used as modulable-resistance channels (memristors, resistive switches, synaptic nodes/synaptic emulators, hysteretic resistors, ReRAM or RRAM, transistors, memtransistors) in the back-end-of-line (BEOL) to introduce computing schemes, such as conductance-based weighting, memristive programming, and neuromorphic computing. These channels can be used to provide a modulable network in the BEOL and enable hardware-based training of the integrated circuit (IC) network. This delivers the hardware-based plasticity of memristive networks (multi-state programming, history-dependent programming/training, and signal property-dependent neuromorphic plasticity) to integrated circuits. In some embodiments, the modulable-resistance channels are provided in the BEOL, while retaining FEOL technologies.

In one or more embodiments, the ultrathin materials described herein are used for memory-dependent computation schemes, making use of these as modulable-resistance channels with modulable resistivity as conductance nodes, whether they be on-off, multi-state, or analogue.

In one or more embodiments, the ultrathin materials described herein are used in memory-plasticity-dependent computation schemes, where the modulable-resistance channels'resistance is modulated by an input voltage/current signal by adjusting the signal's shape, amplitude, duration, rate, and/or inter-signal delay.

In one or more embodiments, the computation schemes using the ultrathin materials described herein as modulable-resistance channels develop a non-von Neumann computing scheme or neuromorphic computing scheme in the BEOL.

One or more embodiments provide methods of forming transition metal dichalcogenides (TMDC) films, other 2D material films, metal oxide films, and nitride films, for memristive channel material applications in back-end-of-line (BEOL) processes. As recognized by one of skill in the art, the films described herein can be combined with any suitable heterostructure material known to the skill artisan. In one or more embodiments, modulable-resistance channels, including, but not limited to, memristors, resistive switches, synaptic nodes/synaptic emulators, hysteretic resistors, ReRAM or RRAM, transistors, and memtransistors are integrated into integrated circuits as nodes and/or channels in the interconnect, thus combining two or more logic nodes, in the back-end-of-the-line (BEOL) and in the front-end-of-the-line (FEOL).

According to one or more embodiments, the methods of forming the modulable-resistance channel materials use an ALD process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction).

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

In other embodiments, the methods of forming the modulable-resistance channel materials use a CVD process. As used herein, the term “chemical vapor deposition” refers to the exposure of at least one reactive species to deposit a layer of material on the substrate surface. In some embodiments, the CVD process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously. As used herein, “substantially simultaneously” means that most of the duration of the first reactive species exposure overlaps with the second reactive species exposure.

Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

In other embodiments, the methods of forming the modulable-resistance channel materials use a physical vapor deposition (PVD) process. Physical vapor deposition (PVD) describes a variety of vacuum deposition methods which can be used to produce thin films and coatings on substrates including metals, ceramics, glass, polymers, and the like. PVD is characterized by a process in which the material transitions from a condensed phase to a vapor phase and then back to a thin film condensed phase. The most common PVD processes are sputtering and evaporation. PVD is used in the manufacturing of items which require thin films for optical, mechanical, electrical, acoustic or chemical functions. Examples include semiconductor devices, microelectromechanical devices, and the like.

One or more of the layers deposited on the substrate or substrate surface as modulable-resistance channel materials are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more embodiments of the disclosure are described with reference to the Figures. One or more embodiments of the disclosure advantageously provide methods for integrating modulable-resistance channels, such as, but not limited to, memristors, resistive switches, synaptic nodes/synaptic emulators, hysteretic resistors, ReRAM or RRAM, transistors, and memtransistors into integrated circuits as nodes or channels in the interconnect, thus combining two or more logic or memory nodes, in the back-end-of-the-line (BEOL) and in the front-end-of-the-line (FEOL).

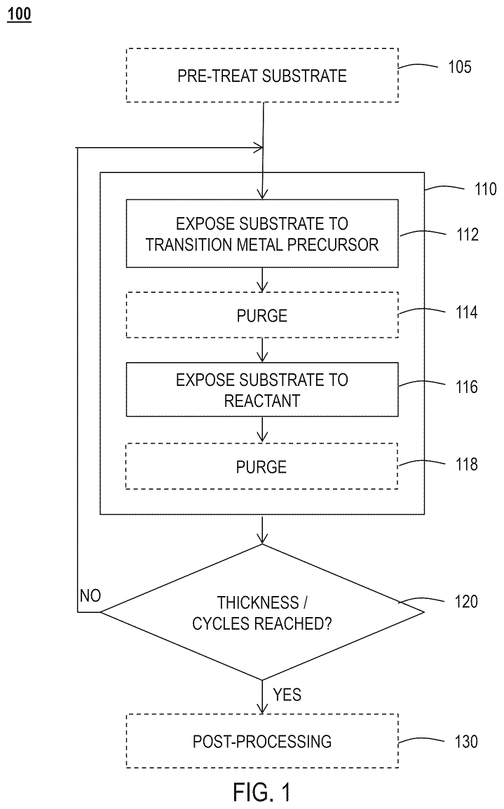

With reference to FIG. 1, one or more embodiments of the disclosure are directed to a method 100 of depositing a film. The method illustrated in FIG. 1 is representative of an ALD process in which the substrate or substrate surface is exposed sequentially to the reactive gases in a manner that prevents or minimizes gas phase reactions of the reactive gases in order form a modulable-resistance channel (memristors, resistive switches, synaptic nodes/synaptic emulators, hysteretic resistors, ReRAM or RRAM, transistors, memtransistors). In some embodiments, the method comprises a CVD process in which the reactive gases are mixed in the processing chamber to allow gas phase reactions of the reactive gases and deposition of the thin film. In other embodiments, the method comprises a physical vapor deposition (PVD) process.

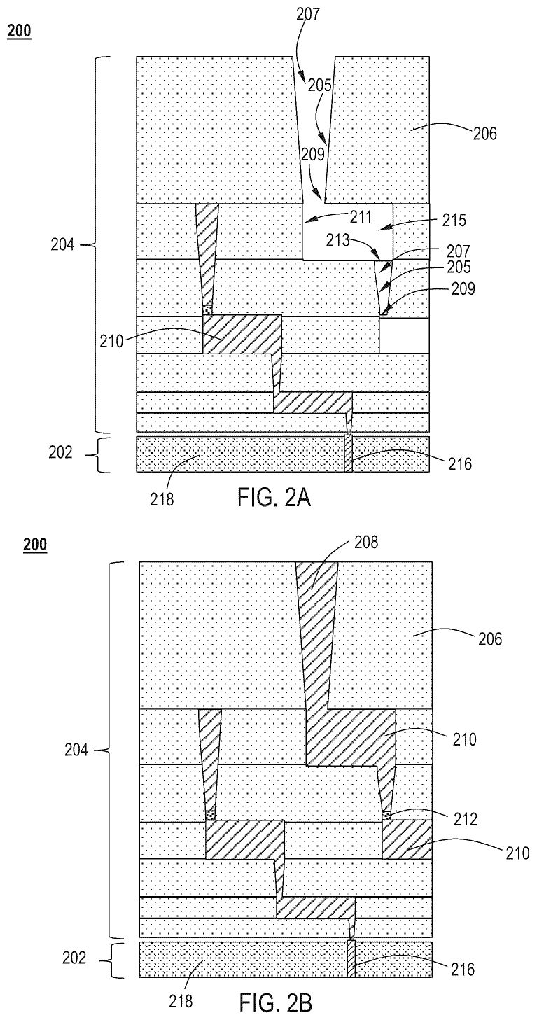

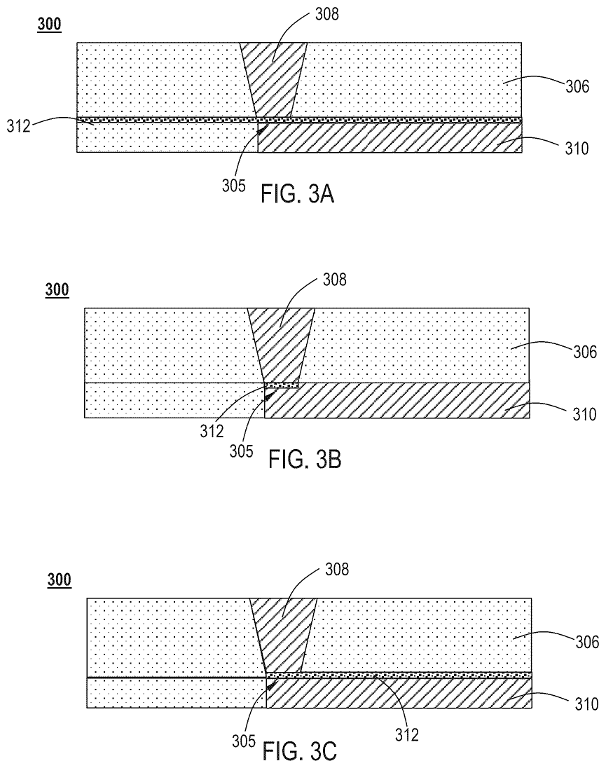

FIGS. 2A and 2B illustrate cross-section schematics of details of one or more layers of the BEOL stacked structures in accordance with one or more embodiments of the disclosure. FIGS. 3A to 3C, 4A to 4C, 5A to 5C, 6A to 6C, 7A to 7C, 8A to 8C, 9A to 9C, 10A to 10C, 11A and 11B, and 12A and 12B illustrate cross-section schematics of integrated circuits in accordance with one or more embodiments of the disclosure.

With reference to FIGS. 2A and 2B, interconnects 200 comprise metal lines 210 that transfer current within the same device layer, and metal vias 208 that transfer current between layers. These metal lines 210 and metal vias 208 are formed with a conductive metal, such as, for example, copper (Cu) or cobalt (Co), in gaps formed within the microelectronic device.

Referring to FIG. 2A, in one or more embodiments, a back-end-of-line (BEOL) 204 includes a dielectric layer 206 which may or may not have one or more feature 207 defining a gap having sidewalls 205 and a bottom 209. In one or more embodiments, the gap 207 includes the metal lines 210 and the metal vias 208 (as illustrated in FIG. 2B). In one or more embodiments, the metal lines 210 have a sidewall 211 and a bottom 213. In one or more embodiments, the metal vias 208 have a sidewall 205 and a bottom 209. As used in this specification and the appended claims, unless specified otherwise, reference to the “bottom of the gap” is intended to mean the bottom of the metal via 208, which is nearest the substrate surface. In one or more embodiments, the device 200 includes a front-end-of-line 202 having a logic or memory terminal 216. The regions 218 separating these terminals can be any non-active part of the FEOL, typically a dielectric region of the substrate.

Embodiments of the disclosure advantageously provide methods of forming TMDC films as modulable-resistance channels (memristors, resistive switches, synaptic nodes/synaptic emulators, hysteretic resistors, ReRAM or RRAM, transistors, memtransistors) in the back-end-of-line (BEOL) 204 of the device to introduce computing schemes, such as conductance-based weighting, memristive programming, and neuromorphic computing. As recognized by one of skill in the art, the films described herein can be combined with any suitable heterostructure material known to the skilled artisan. Accordingly, one or more embodiments delivers the hardware-based plasticity of memristive networks (multi-state programming, history-dependent programming/training, and signal property-dependent neuromorphic plasticity) to integrated circuits, while retaining FEOL technologies.

Transition metal dichalcogenide (TMDC) films, other 2D materials, metal oxide, and nitride films can be formed by ALD, CVD, or PVD for many semiconductor applications. One or more embodiments of the disclosure advantageously provide processes for ALD or CVD to form TMDC, other 2D materials, metal oxide, and nitride films that are integrated into integrated circuits (ICs) as modulable-resistance channels 212 in the interconnect, as illustrated in FIG. 2B. As used in this specification and the appended claims, the term “transition metal dichalcogenide (TMDC) films” refers to a film that comprises transition metal atoms and has greater than or equal to about 1 atomic % of a transition metal, greater than or equal to about 2 atomic % of a transition metal, greater than or equal to about 3 atomic % of a transition metal, greater than or equal to about 4 atomic % of a transition metal, greater than or equal to about 5 atomic % of a transition metal, greater than or equal to about 10 atomic % of a transition metal, greater than or equal to about 15 atomic % of a transition metal, greater than or equal to about 20 atomic % of a transition metal, greater than or equal to about 25 atomic % of a transition metal, greater than or equal to about 30 atomic % of a transition metal, greater than or equal to about 35 atomic % of a transition metal, greater than or equal to about 40 atomic % of a transition metal, greater than or equal to about 45 atomic % of a transition metal, greater than or equal to about 50 atomic % of a transition metal, or greater than or equal to about 60 atomic % of a transition metal.

In one or more embodiments, the transition metal dichalcogenide (TMDC) film may comprise any suitable 2D material known to the skilled artisan. In some embodiments, the 2D material may be an amorphous material, a polycrystalline material, or a crystalline material thereof.

In some embodiments, the transition metal dichalcogenide (TMDC) film has a general formula (I) MX₂, where M is a transition metal and X is a chalcogen.

In one or more embodiments, the transition metal, M, may include any suitable transition metal known to the skilled artisan. In one or more embodiments, the transition metal, M, is selected from one or more of molybdenum (Mo), tungsten (W), tantalum (Ta), titanium (Ti), niobium (Nb), zirconium (Zr), hafnium (Hf), rhenium (Re), platinum (Pt), palladium (Pd), nickel (Ni), and the like.

In one or more embodiments, the chalcogen, X, may include any suitable chalcogenide known to the skilled artisan. In one or more embodiments, the chalcogenide, X, is selected from one or more of sulfur (S), selenium (Se), and tellurium (Te).

In one or more embodiments, the transition metal dichalcogenide (TMDC) film, MX₂, may comprise any suitable transition metal dichalcogenide (TMDC). In one or more embodiments, the transition metal dichalcogenide (TMDC) film is selected from molybdenum sulfide (MoS₂), molybdenum selenide (MoSe₂), molybdenum telluride (MoTe₂), tungsten sulfide (WS₂), tungsten selenide (WSe₂), tungsten telluride (WTe₂), tantalum sulfide (TaS₂), tantalum selenide (TaSe₂), tantalum telluride (TaTe₂), titanium sulfide (TiS₂), titanium selenide (TiSe₂), titanium telluride (TiTe₂), niobium sulfide (NbS₂), niobium selenide (NbSe₂), niobium telluride (NbTe₂), zirconium sulfide (ZrS₂), zirconium selenide (ZrSe₂), zirconium telluride (ZrTe₂), hafnium sulfide (HfS₂), hafnium selenide (HfSe₂), hafnium telluride (HfTe₂), rhenium sulfide (ReS₂), rhenium selenide (ReSe₂), rhenium telluride (ReTe₂), platinum sulfide (PtS₂), platinum selenide (PtSe₂), platinum telluride (PtTe₂), palladium sulfide (PdS₂), palladium selenide (PdSe₂), palladium telluride (PdTe₂), nickel sulfide (NiS₂), nickel selenide (NiSe₂), and nickel telluride (NiTe₂). In other embodiments, the TMDC film may comprise a material where different chalcogenides are mixed. Thus, for example, in one or more embodiments, the TMDC film may have a general chemical formula of MX¹_{y}X²_{2-y}, where X¹ is the first chalcogen element and X² is the second chalcogen element.

In other embodiments, the memristor or memtransistor may comprise a metal oxide film as the modulable-resistance channel 212.

The metal oxide may comprise any suitable metal oxide known to the skilled artisan. In one or more embodiments, the metal oxide has a general formula (II) M′Ox, where M′ is a metal, and Ox represents the oxide.

In other embodiments, the memristor or memtransistor comprise a metal oxide film where the metal oxide material contains more than one metal. Thus, in other embodiments, the metal oxide film may have a general formula (IIa) M^{1′}M^{2′}Ox, where M^{1′} is a metal and M^{2′} is a metal, and Ox represents the oxide. In still further embodiments, the metal oxide film may have a general formula (IIb) M^{1′}M^{2′}M^{3′}Ox, where M^{1′} is a metal, M^{2′} is a metal, and M^{3′} is a metal, and Ox represents the oxide in any stoichiometric proportion.

In one or more embodiments, the metal, M′, M^{1′}, M^{2′}, and M^{3′}, in may include any suitable metal known to the skilled artisan. In one or more embodiments, the metal, M′, M^{1′}, M^{2′}, and M^{3′}, is independently selected from titanium (Ti), tantalum (Ta), aluminum (Al), hafnium (Hf), zirconium (Zr), tungsten (W), silicon (Si), magnesium (Mg), vanadium (V), indium (In), copper (Cu), zinc (Zn), gallium (Ga), gadolinium (Gd), and the like.

In one or more embodiments, the metal oxide film, M′Ox, M^{1′}M^{2′}Ox, or M^{1′}M^{2′}M^{3′}Ox may comprise any suitable transition metal oxide material known to the skilled artisan. In one or more embodiments, the metal oxide film is selected from one or more of titanium oxide (TiOx), tantalum oxide (TaOx), aluminum oxide (AlOx), hafnium oxide (HfOx), zirconium oxide (ZrOx), tungsten oxide (WOx), silicon oxide (SiOx), gallium oxide (GaOx), magnesium oxide (MgOx), vanadium oxide (VOx), indium oxide (InOx), copper oxide (CuOx), zinc oxide (ZnOx), gadolinium oxide (GdOx), and the like. In embodiments, where two or more metals are used, the metal oxide film may comprise, for example, hafnium zirconium oxide (HZO, or HfₓZr₁₋ₓO₂), titanium silicon oxide (TiSiOₓ), hafnium lanthanum oxide (HfLaOx), tungsten silicon oxide (WSiOx), and the like.

In one or more embodiments, the metal oxide film, M′Ox, M^{1′}M^{2′}Ox, or M^{1′}M^{2′}M^{3′}Ox, may be doped with a metal. For example, in one or more embodiments, the metal oxide film, M′Ox, M^{1′}M^{2′}Ox, or M^{1′}M^{2′}M^{3′}Ox, may be doped with copper. In one or more specific embodiments, the metal oxide film, M′Ox, may, for example, comprise copper doped silicon oxide.

The skilled artisan will recognize that the use of molecular formula, e.g., titanium oxide (TiOx), tantalum oxide (TaOx), aluminum oxide (AlOx), hafnium oxide (HfOx), zirconium oxide (ZrOx), tungsten oxide (WOx), silicon oxide (SiOx), magnesium oxide (MgOx), vanadium oxide (VOx), indium oxide (InOx), copper oxide (CuOx), zinc oxide (ZnOx), gallium oxide (GaOx), hafnium zirconium oxide (HZO, or HfₓZr₁₋ₓO₂), titanium silicon oxide (TiSiOₓ), hafnium lanthanum oxide (HfLaOx), tungsten silicon oxide (WSiOx), and the like does not imply a specific stoichiometric relationship between the elements but merely the identity of the major components of the film. For example, TiOx refers to a film whose major composition comprises titanium (Ti) atoms and oxygen (O) atoms. In some embodiments, the major composition of the specified film (i.e., the sum of the atomic percent of the specified atoms) is greater than or equal to about 95%, 98%, 99% or 99.5% of the film, on an atomic basis.

In other embodiments, the memristor or memtransistor may comprise a metal carboxide film as the modulable-resistance channel 212. The metal carboxide may comprise any suitable metal carboxide known to the skilled artisan. In one or more embodiments, the metal oxide has a general formula (III) M′COx, or formula (IIIa) M^{1′}M^{2′}COx, or formula (IIIb) M^{1′}M^{2′}M^{3′}COx, where M′, M^{1′}, M^{2′}, and M^{3′} are independently a metal, C is carbon, and Ox represents the oxide in any stoichiometric proportion.

In one or more embodiments, the metal, M′, M^{1′}, M^{2′}, and M^{3′}, in the metal carboxide films may include any suitable metal known to the skilled artisan. In one or more embodiments, the metal, M′, M^{1′}, M^{2′}, and M^{3′}, of the metal carboxide films is independently selected from titanium (Ti), tantalum (Ta), aluminum (Al), hafnium (Hf), zirconium (Zr), tungsten (W), silicon (Si), magnesium (Mg), vanadium (V), indium (In), copper (Cu), zinc (Zn), gallium (Ga), gadolinium (Gd), and the like.

In other embodiments, the memristor or memtransistor may comprise a metal nitrogen oxide film as the modulable-resistance channel 212. The metal nitrogen oxide film may comprise any suitable metal nitrogen oxide known to the skilled artisan. In one or more embodiments, the metal nitrogen oxide has a general formula (IV) M′NOx, or formula (IVa) M^{1′}M^{2′}NOx, or formula (IVb) M^{1′}M^{2′}M^{3′}NOx, where M′, M^{1′}, M^{2′}, and M^{3′} are independently a metal, N is nitrogen, and Ox represents the oxide in any stoichiometric proportion.

In one or more embodiments, the metal, M′, M^{1′}, M^{2′}, and M^{3′}, of the metal nitrogen oxide films may include any suitable metal known to the skilled artisan. In one or more embodiments, the metal, M′, M^{1′}, M^{2′}, and M^{3′}, of the metal nitrogen oxide films is independently selected from titanium (Ti), tantalum (Ta), aluminum (Al), hafnium (Hf), zirconium (Zr), tungsten (W), silicon (Si), magnesium (Mg), vanadium (V), indium (In), copper (Cu), zinc (Zn), gallium (Ga), gadolinium (Gd), and the like.

In further embodiments, the memristor or memtransistor may comprise a nitride film as the modulable-resistance channel 212.

The metal nitride may comprise any suitable metal nitride or non-metal nitride known to the skilled artisan. In one or more embodiments, the metal nitride or non-metal nitride has a general formula (V) M″ₓN_{y}, where M″ is a metal or non-metal, and N represents the nitride.

In one or more embodiments, the metal or non-metal, M″, may include any suitable metal known to the skilled artisan. In one or more embodiments, the metal, M″, is selected from one or more of titanium (Ti), tantalum (Ta), aluminum (Al), hafnium (Hf), zirconium (Zr), tungsten (W), silicon (Si), and the like.

In one or more embodiments, the nitride film, M″ₓN_{y}, may comprise any suitable metal nitride material or non-metal nitride material known to the skilled artisan. In one or more embodiments, the metal nitride or non-metal nitride is selected from one or more of silicon nitride (Si₃N₄), aluminum nitride (AlN), titanium nitride (TiN), tantalum nitride (TaN), hafnium nitride (HfN), zirconium nitride (ZrN), tungsten nitride (WN), and the like.

In other embodiments, the memristor or memtransistor may comprise a 2D material film as part of the modulable-resistance channel 212. In one or more embodiments, the 2D material film may comprise any suitable 2D material known to the skilled artisan. In one or more embodiments, the 2D material film is selected from one or more of graphene, hexagonal-boron nitride (h-BN), black phosphorus (BP), amorphous carbon, amorphous boron nitride (BN), and the like.

In still further embodiments, the memristor or memtransistor may comprise another suitable material as part of the modulable-resistance channel 212 selected from one or more of indium phosphide (InP), lead titanium oxide (PbTiOx), barium titanium oxide (BaTiOx), strontium titanium oxide (SrTiOx), germanium antimony (GeSb), cobalt-iron-boron (CoFeB), hafnium zirconium oxide (HZO), lead zirconate titanate (PZT), germanium-antimony-tellurium (GST), and the like.

With reference to FIG. 1 and FIGS. 2A-2B, one or more embodiments of the disclosure are directed to a method 100 of depositing a film as a modulable-resistance channel 212 in an integrated circuit 200. In one or more embodiments, the modulable-resistance channel 212 is a memristor or memtransistor formed at the bottom 209 of a metal via 208. In some embodiments, not illustrated, the modulable-resistance channel 212 can be located in one or more of the bottom of the via, the top of the via, and in between metal lines. The method illustrated in FIG. 1 is representative of an ALD process in which the substrate or substrate surface is exposed sequentially to the reactive gases in a manner that prevents or minimizes gas phase reactions of the reactive gases. In some embodiments, the method comprises a CVD process in which the reactive gases are mixed in the processing chamber to allow gas phase reactions of the reactive gases and deposition of the thin film as the modulable-resistance channel 212 in an integrated circuit 200.

In some embodiments, the method 100 includes a pre-treatment operation 105. The pre-treatment can be any suitable pre-treatment known to the skilled artisan. Suitable pre-treatments include, but are not limited to, pre-heating, cleaning, soaking, native oxide removal, or deposition of an adhesion layer (e.g., titanium nitride (TiN)). In one or more embodiments, an adhesion layer, such as titanium nitride, is deposited at operation 105.

At deposition 110, a process is performed to deposit one or more of a TMDC, other 2D material, metal oxide, or the like in the bottom 209 of the metal via 208 to form a modulable-resistance channel 212. The deposition process can include one or more operations to form the TMDC film, other 2D material film, metal oxide film, or the like material film on the substrate. In operation 112, the substrate (or substrate surface) is exposed to a transition metal precursor to deposit a precursor film on the substrate (or substrate surface). The transition metal precursor can be any suitable transition metal-containing compound that can react with (i.e., adsorb or chemisorb onto) the substrate surface to leave a transition metal-containing species on the substrate surface.

In other embodiments, for example, when forming a metal oxide film in the bottom 209 of the metal via 208 to form the modulable-resistance channel 212, at operation 112, the substrate (or substrate surface) is exposed to a metal precursor to deposit a precursor film on the substrate (or substrate surface). The metal precursor can be any suitable metal-containing compound that can react with (i.e., adsorb or chemisorb onto) the substrate surface to leave a metal-containing species on the substrate surface.

In one or more embodiments, the transitional metal precursor comprises a transition metal, M. The transition metal, M, may include any suitable transition metal known to the skilled artisan. In one or more embodiments, the transition metal, M, is selected from one or more of molybdenum (Mo), tungsten (W), tantalum (Ta), titanium (Ti), niobium (Nb), zirconium (Zr), hafnium (Hf), rhenium (Re), platinum (Pt), palladium (Pd), nickel (Ni), zinc (Zn), and the like.

In one or more embodiments, the metal precursor comprises a metal, M′. The metal, M′, may include any suitable metal known to the skilled artisan. In one or more embodiments, the metal, M′, is selected from one or more of titanium (Ti), tantalum (Ta), aluminum (Al), hafnium (Hf), zirconium (Zr), tungsten (W), silicon (Si), magnesium (Mg), vanadium (V), indium (In), copper (Cu), zinc (Zn), gallium (Ga), gadolinium (Gd), and the like.

In one or more embodiments, the metal precursor comprises a metal, M″. The metal, M″, may include any suitable metal known to the skilled artisan. In one or more embodiments, the metal, M″, is selected from one or more of titanium (Ti), tantalum (Ta), aluminum (Al), hafnium (Hf), zirconium (Zr), tungsten (W), silicon (Si), and the like.

As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the transition metal-containing layer, for example, by polishing, etching, reduction, oxidation, halogenation, hydroxylation, annealing, baking, or the like.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate such that the film to form the modulable-resistance channel may be at least partially formed thereon.

In one or more embodiments, as illustrated in FIGS. 2A and 2B, the substrate is a dielectric material 206 where a via opening 207 and a metal line opening 215 are formed. While the portion of the device illustrated in FIGS. 2A and 2B contains multiple layers, one skilled in the art will understand that the growth does not need to be done into an opening that is several layers deep. In one or more embodiments, there is an open via or an open metal line, a layer surface with filled vias or metal lines. The layers above the vias and metal lines can be added after the modulable-resistance channel material has been introduced.

The dielectric material 206 may comprise any suitable dielectric material known to the skilled artisan. As used herein, the term “dielectric material” refers to a layer of material that is an electrical insulator that can be polarized in an electric field. In one or more embodiments, the dielectric layer comprises one or more of oxides, carbon doped oxides, silicon oxide (SiOₓ), silicon nitride (SiN), silicon oxide/silicon nitride, carbides, oxycarbides, nitrides, oxynitrides, oxycarbonitrides, polymers, phosphosilicate glass, fluorosilicate (SiOF) glass, organosilicate glass (SiOCH), silicon carbo nitride (SiCN), and silicon oxycarbo nitrides (SiOCN). In one or more embodiments, the dielectric layer includes, without limitation, furnace, CVD, PVD, ALD and spin-on-coat (SoC) deposited films. In one or more embodiments, the dielectric material may be exposed to in-situ or ex-situ pretreatment and post-treatment process to dope, infuse, implant, heat, freeze, polish, etch, reduce, oxidize, hydroxylate, anneal, UV cure, e-beam cure and/or bake the surface or bulk of the dielectric.

At operation 114, the processing chamber is optionally purged to remove unreacted transitional metal precursor or metal precursor, reaction products and by-products. As used in this manner, the term “processing chamber” also includes portions of a processing chamber adjacent to the substrate surface without encompassing the complete interior volume of the processing chamber. For example, in a sector of a spatially separated processing chamber, the portion of the processing chamber adjacent the substrate surface is purged of the transitional metal precursor or metal precursor by any suitable technique including, but not limited to, moving the substrate through a gas curtain to a portion or sector of the processing chamber that contains none or substantially none of the transitional metal precursor or metal precursor. In one or more embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas comprises one or more of hydrogen (H₂), nitrogen (N₂), helium (He), and argon (Ar).

At operation 116, the substrate (or substrate surface) is exposed to a reactant to form a TMDC film, a 2D material film, or a metal oxide film on the substrate. The reactant can react with the metal-containing species on the substrate surface to form the TMDC film, the other 2D material film, or the metal oxide film.

In one or more embodiments, the reactant comprises a chalcogen-containing precursor. The chalcogen of the chalcogen-containing precursor can be any suitable chalcogen known to the skilled artisan. In one or more embodiments, the chalcogen, is selected from one or more of sulfur (S), selenium (Se), and tellurium (Te).

At operation 118, the processing chamber is optionally purged after exposure to the reactant. Purging the processing chamber in operation 118 can be the same process or different process than the purge in operation 114. Purging the processing chamber removes unreacted reactants from the processing chamber.

At decision 120, the thickness of the deposited film, or number of cycles of transition metal precursor or metal precursor and reactant is considered. If the deposited film has reached a predetermined thickness or a predetermined number of process cycles have been performed, the method 100 moves to an optional post-processing operation 130. In some embodiments, the process cycle comprises sequential exposure of the substrate to the transition metal precursor or metal precursor, purge gas, reactant, and purge gas. If the thickness of the deposited film or the number of process cycles has not reached the predetermined threshold, the method 100 returns to operation 110 to expose the substrate surface to the transition metal precursor or metal precursor again in operation 112 and continuing.

In one or more embodiments, the method 100 comprises, at a temperature in a range of from about 20° C. to 500° C. and at a pressure in a range of from 0.1 mTorr to 760 Torr, sequential pulsing of a transition metal precursor using a carrier gas comprising a mixture of argon (Ar) and hydrogen (H₂) for about 1 to 20 seconds, purging the substrate using a purge gas comprising a mixture of argon (Ar) and hydrogen (H₂), a pulse of a chalcogen-containing precursor using a carrier gas comprising argon (Ar), hydrogen (H₂), nitrogen (N₂), or mixtures of these gases, and the chalcogen-containing precursor for about 1 second to 5 minutes, and purging the substrate using a purge gas comprising argon (Ar), hydrogen (H₂), nitrogen (N₂), or mixtures of these gases to form a transition metal dichalcogenide film as a modulable-resistance channel in an integrated circuit.

In specific embodiments, the method 100 includes, at a temperature in a range of from about 300° C. to 1000° C. and at a pressure in a range of from 0.1 mTorr to 760 Torr, simultaneous pulsing of a transition metal precursor (or a metal precursor) using a carrier gas comprising argon (Ar), hydrogen (H₂), nitrogen (N₂), or mixtures of these gases, and a chalcogen-containing precursor using a carrier gas comprising a mixture of argon (Ar), hydrogen (H₂), nitrogen (N₂), or mixtures of these gases.

The optional post-processing operation 130 can be, for example, a process to modify film properties (e.g., annealing) or a further film deposition process (e.g., additional ALD or CVD processes) to grow additional films. In some embodiments, the optional post-processing operation 130 can be a process that modifies a property of the deposited film. In some embodiments, the optional post-processing operation 130 comprises annealing the as-deposited film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., nitrogen (N₂), argon (Ar)) or a reducing gas (e.g., hydrogen (H₂) or ammonia (NH₃)) or an oxidant, such as, but not limited to, oxygen (O₂), ozone (O₃), deionized (DI) water, or peroxides. Annealing can be performed for any suitable length of time. In some embodiments, the film is annealed for a predetermined time in the range of about 1 second to about 90 minutes. In some embodiments, annealing the as-deposited film increases the density, decreases the resistivity and/or increases the crystallinity of the film.

The method 100 can be performed at any suitable temperature depending on, for example, the transition metal precursor, the metal precursor, the chalcogen-containing precursor, or the thermal budget of the device. In one or more embodiments, the use of high-temperature processing may be undesirable for temperature-sensitive substrates, such as logic devices. In some embodiments, exposure to the transition metal precursor or metal precursor (operation 112) and the chalcogen-containing precursor (operation 116) occur at the same temperature. In some embodiments, the substrate is maintained at a temperature in a range of about 20° C. to about 1000° C.

In some embodiments, exposure to the transition metal precursor or metal precursor (operation 112) occurs at a different temperature than the exposure to the chalcogen-containing precursor (operation 116). In some embodiments, the substrate is maintained at a first temperature in a range of about 20° C. to about 500° C. for the exposure to the transition metal precursor or the metal precursor, and at a second temperature in the range of about 20° C. to about 500° C. for exposure to the chalcogen-containing precursor.

In the embodiment illustrated in FIG. 1, at deposition operation 110 the substrate (or substrate surface) is exposed to the transition metal precursor (or the metal precursor) and the chalcogen-containing precursor sequentially. In another, un-illustrated, embodiment, the substrate (or substrate surface) is exposed to the transition metal precursor (or the metal precursor) and the chalcogen-containing precursor simultaneously in a CVD reaction. In a CVD reaction, the substrate (or substrate surface) can be exposed to a gaseous mixture of the transition metal precursor (or the metal precursor) and chalcogen-containing precursor to deposit the TMDC film, other 2D material film, or the metal oxide film on the substrate having a predetermined thickness. In the CVD reaction, the TMDC film, other 2D material film, or the metal oxide film on the substrate can be deposited in one exposure to the mixed reactive gas or can be multiple exposures to the mixed reactive gas.

The deposition operation 110 can be repeated to form a TMDC film, a 2D material film, or a metal oxide film having a predetermined thickness. In some embodiments, the deposition operation 110 is repeated to provide one or more of TMDC film, 2D material film, or metal oxide film, or on the substrate, such as a film comprising molybdenum sulfide (MoS₂), molybdenum selenide (MoSe₂), molybdenum telluride (MoTe₂), tungsten sulfide (WS₂), tungsten selenide (WSe₂), tungsten telluride (WTe₂), tantalum sulfide (TaS₂), tantalum selenide (TaSe₂), tantalum telluride (TaTe₂), titanium sulfide (TiS₂), titanium selenide (TiSe₂), titanium telluride (TiTe₂), niobium sulfide (NbS₂), niobium selenide (NbSe₂), niobium telluride (NbTe₂), zirconium sulfide (ZrS₂), zirconium selenide (ZrSe₂), zirconium telluride (ZrTe₂), hafnium sulfide (HfS₂), hafnium selenide (HfSe₂), hafnium telluride (HfTe₂), rhenium sulfide (ReS₂), rhenium selenide (ReSe₂), rhenium telluride (ReTe₂), platinum sulfide (PtS₂), platinum selenide (PtSe₂), platinum telluride (PtTe₂), palladium sulfide (PdS₂), palladium selenide (PdSe₂), palladium telluride (PdTe₂), nickel sulfide (NiS₂), nickel selenide (NiSe₂), nickel telluride (NiTe₂), graphene, hexagonal-boron nitride (h-BN), black phosphorus (BP), amorphous carbon, amorphous boron nitride (BN), indium phosphide (InP), zinc sulfide (ZnS), zinc selenide (ZnSe), zinc telluride (ZnTe), titanium oxide (TiOx), tantalum oxide (TaOx), one or more of titanium oxide (TiOx), tantalum oxide (TaOx), aluminum oxide (AlOx), hafnium oxide (HfOx), zirconium oxide (ZrOx), tungsten oxide (WOx), silicon oxide (SiOx), gallium oxide (GaOx), magnesium oxide (MgOx), vanadium oxide (VOx), indium oxide (InOx), copper oxide (CuOx), zinc oxide (ZnOx), gadolinium oxide (GdOx), doped silicon oxide (e.g., Cu-doped SiOx), lead titanium oxide (PbTiO₃), barium titanium oxide (BaTiO₃), strontium titanium oxide (SrTiO₃), germanium antimony (GeSb), cobalt-iron-boron (CoFeB), hafnium zirconium oxide (HZO), hafnium lanthanum oxide (HfLaOx), tungsten silicon oxide (WSiOx), lead zirconate titanate (PZT), germanium-antimony-tellurium (GST), and the like having a thickness in the range of about 0.3 nm to about 100 nm, or in the range of about 30 Å to about 10 μm.

One or more embodiments of the disclosure are directed to methods of depositing a TMDC film, a 2D material, or a metal oxide film in a high aspect ratio feature. A high aspect ratio feature is a trench, via, or pillar having a height: width ratio greater than or equal to about 10, 20, 50, 100, or more. In some embodiments, the TMDC film, the 2D material film, or the metal oxide film is deposited conformally on/in the high aspect ratio feature. As used in this manner, a conformal film has a thickness near the top of the feature that is in the range of about 80 to 120% of the thickness at the bottom of the feature.

Some embodiments of the disclosure are directed to methods for bottom-up gap fill of a feature. A bottom-up gap fill process fills the feature from the bottom versus a conformal process which fills the feature from the bottom and sides.

FIGS. 3A to 3C, 4A to 4C, 5A to 5C, 6A to 6C, 7A to 7C, 8A to 8C, 9A to 9C, 10A to 10C, 11A and 11B, and 12A and 12B illustrate cross-section schematics of portions of integrated circuits in accordance with one or more embodiments of the disclosure. Any of the ALD processes, CVD processes, and PVD processes described herein may be used to form the modulable-resistance channels (memristors, resistive switches, synaptic nodes/synaptic emulators, hysteretic resistors, ReRAM or RRAM, transistors, memtransistors) in back-end-of-line (BEOL) structures depicted in FIGS. 3A to 3C, 4A to 4C, 5A to 5C, 6A to 6C, 7A to 7C, 8A to 8C, 9A to 9C, 10A to 10C, 11A and 11B, and 12A and 12B.

With reference to FIGS. 3A to 3C, interconnects 300 comprise metal lines 310 that transfer current within the same device layer, and metal vias 308 that transfer current between layers. These metal lines 310 and metal vias 308 are formed with a conductive metal, such as, for example, copper (Cu) or cobalt (Co), in gaps formed within the microelectronic device.

Referring to FIG. 3A, in one or more embodiments, a BEOL device 300 includes a vertical channel 305 and a modulable-resistance channel material 312 therein. Any of the ALD processes, CVD processes, and PVD processes described herein and any of the transition metal and oxide materials disclosed herein may be used to form the modulable-resistance channel material 312 (memristors, resistive switches, synaptic nodes/synaptic emulators, hysteretic resistors, ReRAM or RRAM, transistors, memtransistors). As illustrated in FIGS. 3A to 3C, the vertical channel 305 may be patterned or unpatterned. It will be appreciated by one of skill in the art that there does not need to be a gap between the two BEOL layers. In one or more embodiments, if the vertical channel 305 is grown while the open via is already there, the deposition will occur only at the bottom of the via (as well as the wall of the via and surface of 306 dielectric).

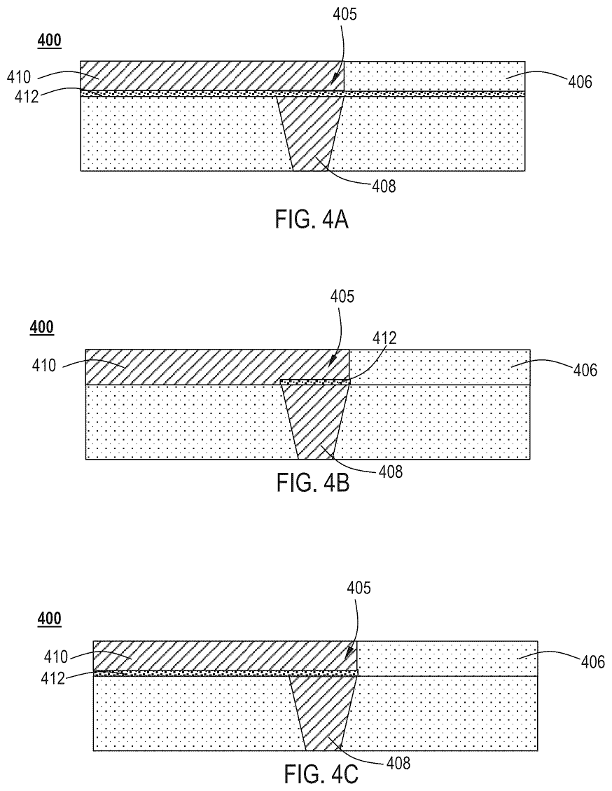

With reference to FIGS. 4A to 4C, interconnects 400 comprise metal lines 410 that transfer current within the same device layer, and metal vias 408 that transfer current between layers. These metal lines 410 and metal vias 408 are formed with a conductive metal, such as, for example, copper (Cu) or cobalt (Co), in gaps formed within the microelectronic device.

Referring to FIG. 4A, in one or more embodiments, a BEOL device 400 includes a vertical channel 405 and a modulable-resistance channel material 412 therein. Any of the ALD processes (CVD) processes, and (PVD) processes described herein and any of the transition metal and oxide materials disclosed herein may be used to form the modulable-resistance channel material 412 (memristors, resistive switches, synaptic nodes/synaptic emulators, hysteretic resistors, ReRAM or RRAM, transistors, memtransistors). As illustrated in FIGS. 4A to 4C, the vertical channel 405 may be patterned or unpatterned. It will be appreciated by one of skill in the art that there does not need to be a gap between the two BEOL layers.

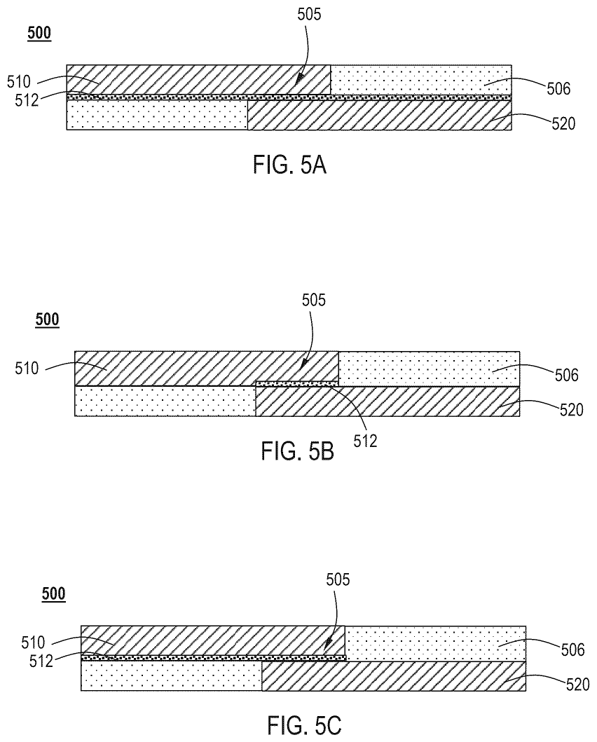

With reference to FIGS. 5A to 5C, interconnects 500 comprise a first metal line 510 that transfers current within the same device layer, and a second metal line 520 that transfers current within the same device layer. These first metal line 510 and the second metal line 520 are formed with a conductive metal, such as, for example, copper (Cu) or cobalt (Co), in gaps formed within the microelectronic device.

Referring to FIG. 5A, in one or more embodiments, a (BEOL) device 500 includes a vertical channel 505 and a modulable-resistance channel material 512 therein. Any of the (ALD) processes, (CVD) processes, and (PVD) processes described herein and any of the transition metal and oxide materials disclosed herein may be used to form the modulable-resistance channel material 512 (memristors, resistive switches, synaptic nodes/synaptic emulators, hysteretic resistors, ReRAM or RRAM, transistors, memtransistors). As illustrated in FIGS. 5A to 5C, the vertical channel 505 may be patterned or unpatterned. It will be appreciated by one of skill in the art that there does not need to be a gap between the two BEOL layers.

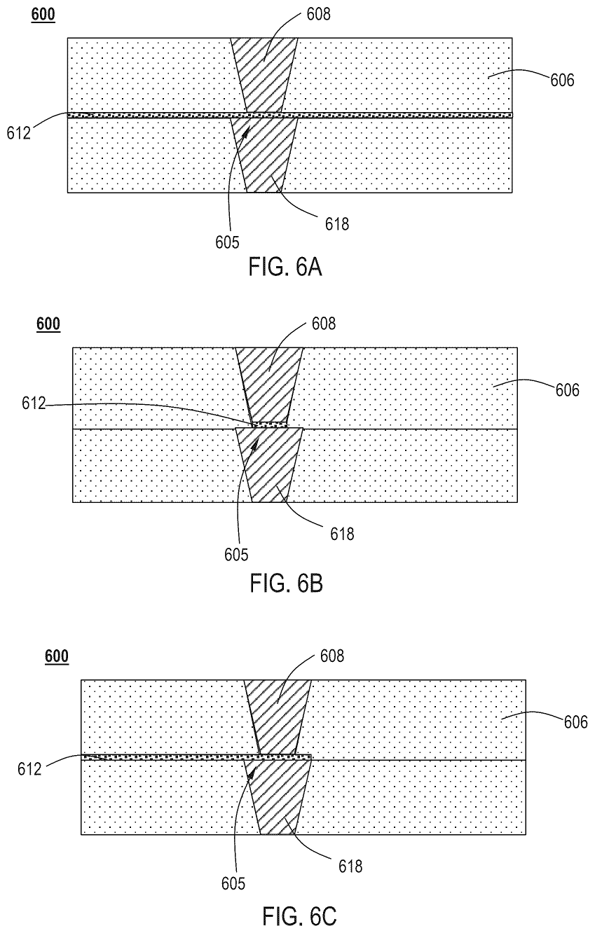

With reference to FIGS. 6A to 6C, interconnects 600 comprise a first metal via 608 that transfers current between layers, and a second metal via 618 that transfers current between layers. The first metal via 608 and the second metal via 618 are formed with a conductive metal, such as, for example, copper (Cu) or cobalt (Co), in gaps formed within the microelectronic device.

Referring to FIG. 6A, in one or more embodiments, a back-end-of-line (BEOL) device 600 includes a vertical channel 605 and a modulable-resistance channel material 612 therein. Any of the ALD processes, CVD processes, and PVD processes described herein and any of the transition metal and oxide materials disclosed herein may be used to form the modulable-resistance channel material 612 (memristors, resistive switches, synaptic nodes/synaptic emulators, hysteretic resistors, ReRAM or RRAM, transistors, memtransistors). As illustrated in FIGS. 6A to 6C, the vertical channel 605 may be patterned or unpatterned. It will be appreciated by one of skill in the art that there does not need to be a gap between the two BEOL layers.

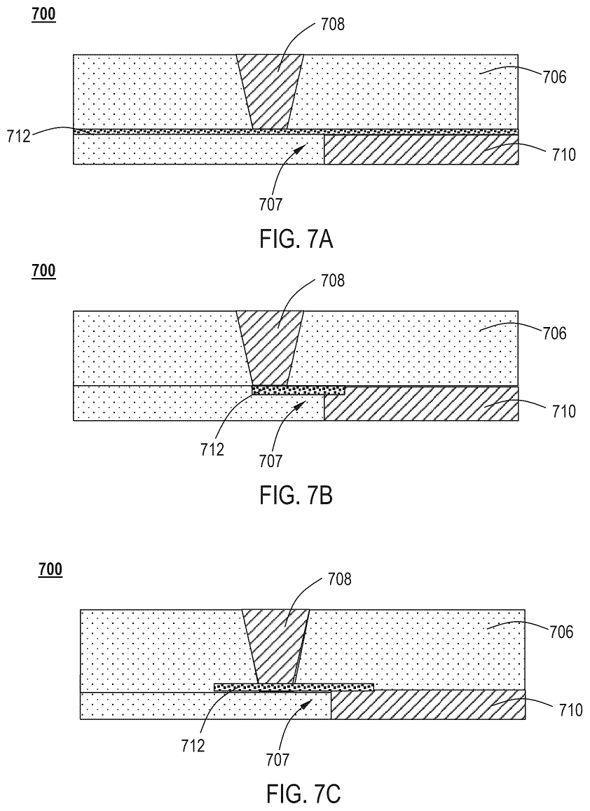

With reference to FIGS. 7A to 7C, interconnects 700 comprise metal lines 710 that transfer current within the same device layer, and metal vias 708 that transfer current between layers. These metal lines 710 and metal vias 708 are formed with a conductive metal, such as, for example, copper (Cu) or cobalt (Co), in gaps formed within the microelectronic device.

Referring to FIG. 7A, in one or more embodiments, a BEOL device 700 includes a horizontal channel 707 and a modulable-resistance channel material 712 therein. Any of the ALD processes, CVD processes, and PVD processes described herein and any of the transition metal and oxide materials disclosed herein may be used to form the modulable-resistance channel material 712 (memristors, resistive switches, synaptic nodes/synaptic emulators, hysteretic resistors, ReRAM or RRAM, transistors, memtransistors). As illustrated in FIGS. 7A to 7C, the horizontal channel 707 may be patterned or unpatterned. It will be appreciated by one of skill in the art that there does not need to be a gap between the two BEOL layers.

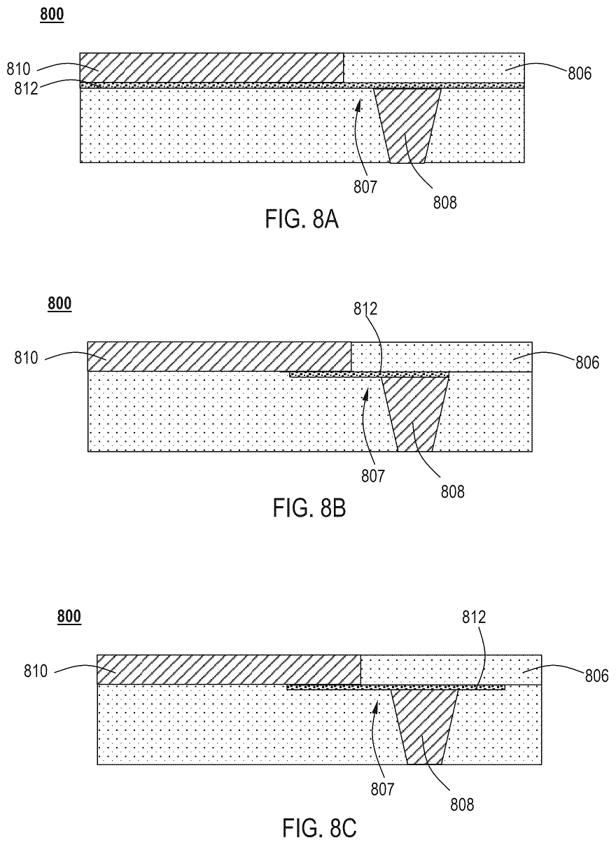

With reference to FIGS. 8A to 8C, interconnects 800 comprise metal lines 810 that transfer current within the same device layer, and metal vias 808 that transfer current between layers. These metal lines 810 and metal vias 808 are formed with a conductive metal, such as, for example, copper (Cu) or cobalt (Co), in gaps formed within the microelectronic device.

Referring to FIG. 8A, in one or more embodiments, a BEOL device 800 includes a horizontal channel 807 and a modulable-resistance channel material 812 therein. Any of the ALD processes, CVD processes, and PVD processes described herein and any of the transition metal and oxide materials disclosed herein may be used to form the modulable-resistance channel material 812 (memristors, resistive switches, synaptic nodes/synaptic emulators, hysteretic resistors, ReRAM or RRAM, transistors, memtransistors). As illustrated in FIGS. 8A to 8C, the horizontal channel 807 may be patterned or unpatterned. It will be appreciated by one of skill in the art that there does not need to be a gap between the two BEOL layers.

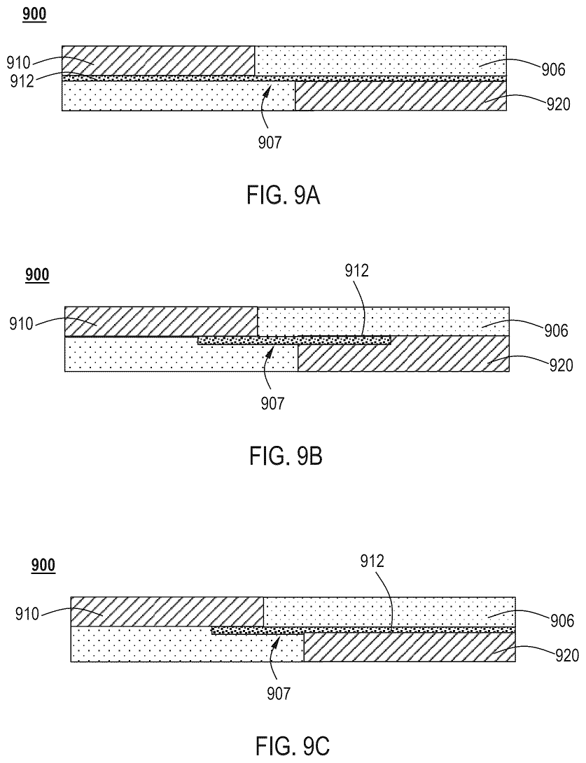

With reference to FIGS. 9A to 9C, interconnects 900 comprise a first metal line 910 that transfers current within the same device layer, and a second metal line 920 that transfer current with the same device layer. The first metal line 910 and the second metal line 920 are formed with a conductive metal, such as, for example, copper (Cu) or cobalt (Co), in gaps formed within the microelectronic device.

Referring to FIG. 9A, in one or more embodiments, a BEOL device 900 includes a horizontal channel 907 and a modulable-resistance channel material 912 therein. Any of the ALD processes, CVD processes, and PVD processes described herein and any of the transition metal and oxide materials disclosed herein may be used to form the modulable-resistance channel material 912 (memristors, resistive switches, synaptic nodes/synaptic emulators, hysteretic resistors, ReRAM or RRAM, transistors, memtransistors). As illustrated in FIGS. 9A to 9C, the horizontal channel 707 may be patterned or unpatterned. It will be appreciated by one of skill in the art that there does not need to be a gap between the two BEOL layers.

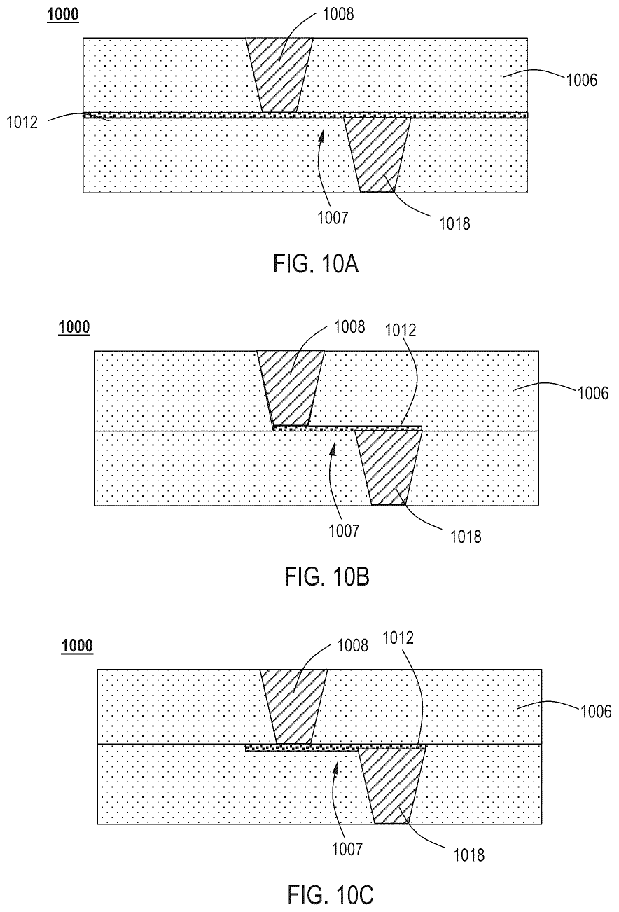

With reference to FIGS. 10A to 10C, interconnects 1000 comprise a first metal via 1008 that transfers current between layers, and a second metal via 1018 that transfers current between layers. The first metal via 1008 and the second metal via 1018 are formed with a conductive metal, such as, for example, copper (Cu) or cobalt (Co), in gaps formed within the microelectronic device.

Referring to FIG. 10A, in one or more embodiments, a BEOL device 1000 includes a horizontal channel 1007 and a modulable-resistance channel material 1012 therein. Any of the ALD processes, CVD processes, and PVD processes described herein and any of the transition metal and oxide materials disclosed herein may be used to form the modulable-resistance channel material 1012 (memristors, resistive switches, synaptic nodes/synaptic emulators, hysteretic resistors, ReRAM or RRAM, transistors, memtransistors). As illustrated in FIGS. 10A to 10C, the vertical channel 1007 may be patterned or unpatterned. It will be appreciated by one of skill in the art that there does not need to be a gap between the two BEOL layers.

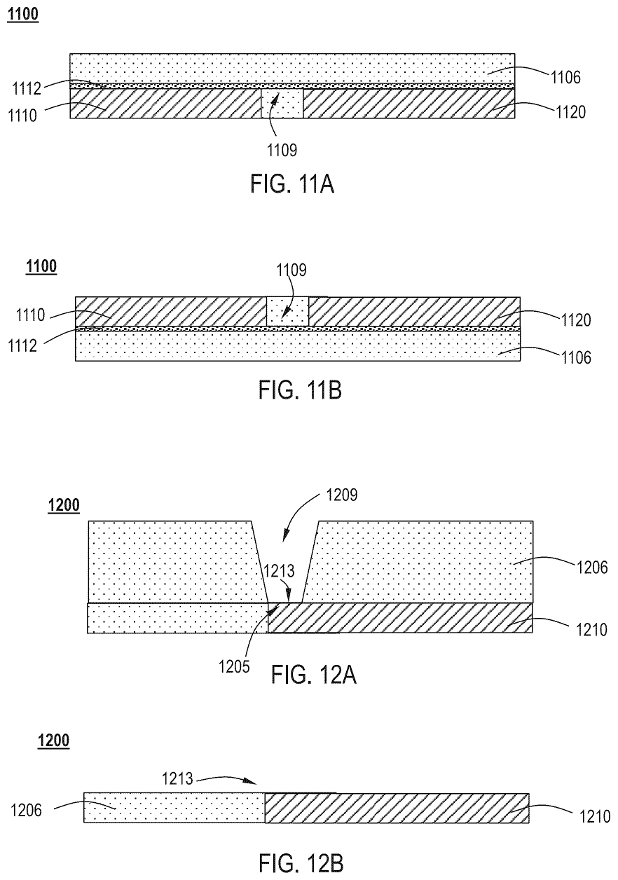

With reference to FIGS. 11A and 11B, interconnects 1100 comprise a first metal line 1110 that transfers current within the same device layer, and a second metal line 1120 that transfers current with the same device layer as the first metal line 1110. The first metal line 1110 and the second metal line 1120 are formed with a conductive metal, such as, for example, copper (Cu) or cobalt (Co), in gaps formed within the microelectronic device.

Referring to FIGS. 11A and 11B, in one or more embodiments, a BEOL device 1100 includes a horizontal channel 1109 and a modulable-resistance channel material 1112 therein. A dielectric layer 1106 may be formed on the modulable-resistance channel material 1112. Any of the ALD processes, CVD processes, and PVD processes described herein and any of the transition metal and oxide materials disclosed herein may be used to form the modulable-resistance channel material 1112 (memristors, resistive switches, synaptic nodes/synaptic emulators, hysteretic resistors, ReRAM or RRAM, transistors, memtransistors). As illustrated in FIGS. 11A and 11B, the horizontal channel 1109 may be patterned or unpatterned. It will be appreciated by one of skill in the art that there does not need to be a gap between the two BEOL layers.

In any of the embodiments described herein, as illustrated in FIG. 12A, the growth of the modulable-resistance channel 1213 may have a dielectric layer 1206 on the modulable-resistance channel 1213. In one or more embodiments, the modulable-resistance channel 1213 may be patterned or unpatterned. It will be appreciated by one of skill in the art that there does not need to be a gap between the two BEOL layers. In one or more embodiments, the growth of the channel material can be done into an open via or an open metal line (FIG. 12A) or simply on top of a layer that already has filled vias or metal lines (FIG. 12B). In other embodiments, as illustrated in FIG. 12B, the growth of the modulable-resistance channel 1213 may not have a dielectric layer on the modulable-resistance channel 1213.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at the front end of the cluster tool. Any suitable cluster tool known to the skilled artisan may be used, and the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as rapid thermal processing (RTP), plasma nitridation, degas, orientation, hydroxylation, and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrate are individually loaded into the first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled locally to change the substrate temperature. In some embodiments, a heater/cooler is positioned within the chamber adjacent to the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1: Atomic Layer Deposition of Transition Metal Dichalcogenide Films

General procedure: At a temperature in a range of from 20° C. to 500° C., and a pressure in a range of from 0.1 mTorr to 760 Torr, a silicon substrate having a via opening formed therein is placed in a processing chamber. A transition metal precursor is flowed into the processing chamber in an atmosphere of argon (Ar) or nitrogen (N₂) gas over the silicon substrate leaving a transition metal-precursor terminated surface. Unreacted precursor and byproducts are then purged out of the chamber. Next, a chalcogen-containing precursor is then introduced into the chamber that reacts with the surface-bound transition metal species. Again, excess chalcogen-containing precursor and byproducts are removed from the chamber. The resultant material formed in the via opening is a transition metal dichalcogenide film.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a modulable-resistance channel on a substrate, the method comprising:
exposing a substrate to metal precursor, the substrate comprising an opening formed in a dielectric layer; and
exposing the substrate to a second precursor to form the modulable-resistance channel in the opening.

2. The method of claim 1, wherein the modulable-resistance channel comprises one or more of a transition metal dichalcogenide (TMDC) film, a 2D material film, a metal oxide film, a metal carboxide film, a metal nitride oxide film, and a nitride film.

3. The method of claim 2, wherein the transition metal dichalcogenide (TMDC) film is selected from molybdenum sulfide (MoS₂), molybdenum selenide (MoSe₂), molybdenum telluride (MoTe₂), tungsten sulfide (WS₂), tungsten selenide (WSe₂), tungsten telluride (WTe₂), tantalum sulfide (TaS₂), tantalum selenide (TaSe₂), tantalum telluride (TaTe₂), titanium sulfide (TiS₂), titanium selenide (TiSe₂), titanium telluride (TiTe₂), niobium sulfide (NbS₂), niobium selenide (NbSe₂), niobium telluride (NbTe₂), zirconium sulfide (ZrS₂), zirconium selenide (ZrSe₂), zirconium telluride (ZrTe₂), hafnium sulfide (HfS₂), hafnium selenide (HfSe₂), hafnium telluride (HfTe₂), rhenium sulfide (ReS₂), rhenium selenide (ReSe₂), rhenium telluride (ReTe₂), platinum sulfide (PtS₂), platinum selenide (PtSe₂), platinum telluride (PtTe₂), palladium sulfide (PdS₂), palladium selenide (PdSe₂), palladium telluride (PdTe₂), nickel sulfide (NiS₂), nickel selenide (NiSe₂), and nickel telluride (NiTe₂).

4. The method of claim 2, wherein metal oxide film has a general formula of M′Ox, M^{1′}M^{2′}Ox, or M^{1′}M^{2′}M^{3′}Ox, wherein the metal carboxide film has a general formula of the metal oxide has a general formula M′COx, M^{1′}M^{2′}COx, or M^{1′}M^{2′}M^{3′}COx, wherein the metal nitrogen oxide film has a general formula M′NOx, M^{1′}M^{2′}NOx, or M^{1′}M^{2′}M^{3′}NOx, wherein M′, M^{1′}, M^{2′}, and M^{3′} are a metal independently selected from titanium (Ti), tantalum (Ta), aluminum (Al), hafnium (Hf), zirconium (Zr), tungsten (W), silicon (Si), magnesium (Mg), vanadium (V), indium (In), copper (Cu), zinc (Zn), gallium (Ga), and gadolinium (Gd), and wherein Ox is an oxide, C is carbon, and N is nitrogen.

5. The method of claim 2, wherein the nitride film has a general formula M″ₓN_{y}, where M″ is a metal or non-metal selected from one or more of titanium (Ti), tantalum (Ta), aluminum (Al), hafnium (Hf), zirconium (Zr), tungsten (W), and silicon (Si), and N is nitrogen.

6. The method of claim 2, wherein the 2D material film is selected from one or more of graphene, hexagonal-boron nitride (h-BN), black phosphorus (BP), amorphous carbon, amorphous boron nitride (BN), and indium phosphide (InP).

7. The method of claim 1, wherein the modulable-resistance channel comprises one or more of lead titanium oxide (PbTiO₃), barium titanium oxide (BaTiO₃), strontium titanium oxide (SrTiO₃), germanium antimony (GeSb), cobalt-iron-boron (CoFeB), lead zirconate titanate (PZT), and germanium-antimony-tellurium (GST).

8. The method of claim 1, wherein the metal precursor comprises a metal selected from one or more of molybdenum (Mo), tungsten (W), tantalum (Ta), titanium (Ti), niobium (Nb), zirconium (Zr), hafnium (Hf), rhenium (Re), platinum (Pt), palladium (Pd), nickel (Ni), zinc (Zn), aluminum (Al), silicon (Si), magnesium (Mg), vanadium (V), indium (In), copper (Cu), zinc (Zn), gallium (Ga), and gadolinium (Gd).

9. The method of claim 1, wherein the second precursor is a chalcogen-containing including a chalcogen selected from one or more of sulfur (S), selenium (Se), and tellurium (Te).

10. The method of claim 1, wherein the method is one or more of chemical vapor deposition (CVD), atomic layer deposition (ALD), and physical vapor deposition (PVD).

11. The method of claim 1, wherein the second precursor is reacted with the metal precursor at a temperature in a range of from 20° C. to 1000° C.

12. The method of claim 1, further comprising repeating the method to provide a memristor having a thickness of about 0.3 nm to about 1000 nm.

13. The method of claim 1, wherein the substrate is exposed to the metal precursor and the second precursor sequentially or simultaneously.

14. The method of claim 1, further comprising purging the substrate of the metal precursor prior to exposing the substrate to the second precursor, wherein purging comprises one or more of applying a vacuum or flowing a purge gas over the substrate, and wherein the purge gas selected from one or more of hydrogen (H₂), nitrogen (N₂), helium (He), and argon (Ar).

15. A method of forming a memristor on a semiconductor substrate, the method comprising:
forming a memristor in a process cycle comprising sequential exposure of a substrate to a metal precursor, a first purge gas, a chalcogen-containing precursor, and a second purge gas, the substrate comprising a dielectric layer having a via opening formed therein, the memristor formed in the via opening as an integrated circuit node.

16. The method of claim 15, wherein the wherein the chalcogen-containing precursor contains a chalcogen selected from one or more of sulfur (S), selenium (Se), and tellurium (Te).

17. The method of claim 15, wherein the modulable-resistance channel comprises one or more of a transition metal dichalcogenide (TMDC) film, a 2D material film, a metal oxide film, a metal carboxide film, a metal nitride oxide film, and a nitride film.

18. The method of claim 17, wherein the transition metal dichalcogenide (TMDC) film is selected from molybdenum sulfide (MoS₂), molybdenum selenide (MoSe₂), molybdenum telluride (MoTe₂),, tungsten sulfide (WS₂), tungsten selenide (WSe₂), tungsten telluride (WTe₂), tantalum sulfide (TaS₂), tantalum selenide (TaSe₂), tantalum telluride (TaTe₂), titanium sulfide (TiS₂), titanium selenide (TiSe₂), titanium telluride (TiTe₂), niobium sulfide (NbS₂), niobium selenide (NbSe₂), niobium telluride (NbTe₂), zirconium sulfide (ZrS₂), zirconium selenide (ZrSe₂), zirconium telluride (ZrTe₂), hafnium sulfide (HfS₂), hafnium selenide (HfSe₂), hafnium telluride (HfTe₂), rhenium sulfide (ReS₂), rhenium selenide (ReSe₂), rhenium telluride (ReTe₂), platinum sulfide (PtS₂), platinum selenide (PtSe₂), platinum telluride (PtTe₂), palladium sulfide (PdS₂), palladium selenide (PdSe₂), palladium telluride (PdTe₂), nickel sulfide (NiS₂), nickel selenide (NiSe₂), and nickel telluride (NiTe₂).

19. The method of claim 17, wherein metal oxide film has a general formula of M′Ox, M^{1′}M^{2′}Ox, or M^{1′}M^{2′}M^{3′}Ox, wherein the metal carboxide film has a general formula of the metal oxide has a general formula M′COx, M^{1′}M^{2′}COx, or M^{1′}M^{2′}M^{3′}COx, wherein the metal nitrogen oxide film has a general formula M′NOx, M^{1′}M^{2′}NOx, or M^{1′}M^{2′}M^{3′}NOx, where M′, M^{1′}, M^{2′}, and M³′ are a metal independently selected from titanium (Ti), tantalum (Ta), aluminum (Al), hafnium (Hf), zirconium (Zr), tungsten (W), silicon (Si), magnesium (Mg), vanadium (V), indium (In), copper (Cu), zinc (Zn), gallium (Ga), and gadolinium (Gd), and wherein N is nitrogen, C is carbon, and Ox is an oxide.

20. The method of claim 17, wherein the nitride film has a general formula M″ₓN_{y}, where M″ is a metal or non-metal selected from one or more of titanium (Ti), tantalum (Ta), aluminum (Al), hafnium (Hf), zirconium (Zr), tungsten (W), and silicon (Si), and wherein N is nitrogen.

21. The method of claim 17, wherein the 2D material film is selected from one or more of graphene, hexagonal-boron nitride (h-BN), black phosphorus (BP), amorphous carbon, amorphous boron nitride (BN), and indium phosphide (InP).

22. The method of claim 15, wherein the memristor comprises one or more of lead titanium oxide (PbTiO₃), barium titanium oxide (BaTiO₃), strontium titanium oxide (SrTiO₃), germanium antimony (GeSb), cobalt-iron-boron (CoFeB), lead zirconate titanate (PZT), and germanium-antimony-tellurium (GST).

23. The method of claim 15, wherein the metal precursor comprises a metal selected from one or more of molybdenum (Mo), tungsten (W), tantalum (Ta), titanium (Ti), niobium (Nb), zirconium (Zr), hafnium (Hf), rhenium (Re), platinum (Pt), palladium (Pd), nickel (Ni), zinc (Zn), aluminum (Al), silicon (Si), magnesium (Mg), vanadium (V), indium (In), copper (Cu), zinc (Zn), gallium (Ga), and gadolinium (Gd).

24. The method of claim 15, wherein the chalcogen-containing precursor is reacted with the metal precursor at a temperature in a range of from 20° C. to 1000° C.

25. The method of claim 15, further comprising repeating the process cycle to provide a memristor having a thickness of about 0.3 nm to about 1000 nm.

26. The method of claim 15, wherein the first purge gas and the second purge gas are independently selected from one or more of hydrogen (H₂), nitrogen (N₂), helium (He), and argon (Ar).
